(19) United States
(12) Patent Application Publication
(10) Pub. No.: US 2015/0235845 A1
(43) Pub. Date: Aug. 20, 2015

(54) METHOD OF MANUFACTURING SEMICONDUCTOR DEVICE

(71) Applicant: TERA PROBE, INC., Yokohama (JP)

(72) Inventors: Nobuatsu SEKITA, Fuchu-shi (JP); Tsutomu MIYAMOTO, Tama-shi (JP); Norihiko KANEKO, Fussa-shi (JP); Ichiro KONO, Higashiyamato-shi (JP)

(73) Assignee: TERA PROBE, INC., Yokohama (JP)

(21) Appl. No.: 14/625,411

(22) Filed: Feb. 18, 2015

(30) Foreign Application Priority Data
Feb. 20, 2014 (JP) 2014-030548
Dec. 19, 2014 (JP) 2014-257404

(51) Int. Cl. H01L 21/02; H01L 21/768; H01L 21/027; H01L 21/3105; H01L 21/311; H01L 23/00

(52) U.S. Cl. CPC H01L 21/02288; H01L 21/31144; H01L 24/11; H01L 21/0274; H01L 21/3105; H01L 21/02118; H01L 21/768; H01L 24/03; H01L 21/76898; H01L 2224/11622; H01L 2924/01029; H01L 2924/07025; H01L 2224/03622

(57) ABSTRACT

According to one embodiment, a method of manufacturing a semiconductor device, includes preparing a semiconductor substrate includes a connection pad to electrically connect to a circuit element formed on a main surface, or a rewiring line connected to the connection pad, forming an insulating photosensitive resin film on the substrate with the exclusion of at least an edge portion of the substrate by inkjet, patterning the photosensitive resin film by photolithography, and forming a rewiring line, UBM or an electrode for external connection on the substrate on which the patterned photosensitive resin film is formed.

### CROSS-REFERENCE TO RELATED APPLICATIONS

This application is based upon and claims the benefit of priority from prior Japanese Patent Applications No. 2014-030548, filed Feb. 20, 2014; and No. 2014-257404, filed Dec. 19, 2014, the entire contents of all of which are incorporated herein by reference.

### BACKGROUND OF THE INVENTION

1. Field of the Invention

The present invention relates to a method of manufacturing, in which pattern formation by an inkjet and pattern formation by photolithography are combined.

2. Description of the Related Art

Conventionally, for the formation of a pattern of a protective film, a sealing film or the like on a semiconductor wafer in the process of a chip-size package (CSP), a pattern formation method by the lithography, that of the inkjet, etc., are used or developed.

In the pattern formation method by the photolithography, a photosensitive resin film (resist) is formed on a semiconductor wafer by spin-coating, and thereafter the resin film is selectively irradiated with light, thereby forming patterns of openings for connection pads, dicing lines and the like. But with spin-coating, 80 to 90% or even more of the photosensitive resin, which is expensive, is wastefully scattered by centrifugal force. Further, since it is difficult to prevent photosensitive resin from finding its way around to the rear surface of the wafer, the following drawbacks may result. That is, a washing step for removing the resin formed on the rear surface of the wafer needs to be provided. Further, since the influence of the centrifugal force and wind pressure produced by rotation is great, the thickness of the resin film varies from the central portion to an outer edge portion of the wafer, or the shape of the resin film becomes uneven due to irregularities on the wafer. Furthermore, since the exposure depth of the photolithography is limited, insufficient exposure may occur for thick portion of resin films.

On the other hand, in the pattern formation method by the inkjet, the waste of resin can be avoided since resin is provided only in a region where a pattern should be formed. But the inkjet device employs an inkjet head having a nozzle diameter of, for example, about 50 μm, the accuracy of landing of droplets varies by, for example, about ±20 μm. With this accuracy, it is not possible to form a pattern of such high precision that is required for a CSP processing step for forming an opening of an insulation film at an accuracy of 1 to 2 μm on an aluminum pad having a length of one side of, for example, 50 μm. Here, the accuracy can be improved by reducing the nozzle diameter, but when the diameter of droplets is reduced to, for example, 1/10, the number of droplets necessary to form the same area and thickness is multiplied by 1000. For this reason, even if the application speed is increased and the number of heads is increased, etc. for improvement, a large decrease in throughput is inevitable.

As described above, conventionally, in the pattern formation of a photosensitive resin applied by spin coating by the photolithography, the photosensitive resin is wasted. On the other hand, a high-accuracy pattern cannot be formed by inkjet.

### BRIEF SUMMARY OF THE INVENTION

According to the present invention, there is provided a method of manufacturing a semiconductor device, comprising: preparing a semiconductor substrate comprising a connection pad to electrically connect to a circuit element formed on a main surface, or a rewiring line connected to the connection pad; forming an insulating photosensitive resin film on the substrate with an exclusion of at least an edge portion of the substrate by inkjet; patterning the photosensitive resin film by photolithography; and forming a rewiring line, UBM or an electrode for external connection on the substrate on which the patterned photosensitive resin film is formed.

Additional objects and advantages of the invention will be set forth in the description which follows, and in part will be obvious from the description, or may be learned by practice of the invention. The objects and advantages of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate embodiments of the invention, and together with the general description given above and the detailed description of the embodiments given below, serve to explain the principles of the invention.

FIG. 1 is a cross-section showing a brief structure of a semiconductor device according to the first embodiment;

FIGS. 2A to 2G are cross-sections each showing a manufacturing step of the semiconductor device shown in FIG. 1;

FIGS. 3A and 3B are plan views each showing a pattern of a photosensitive resin film to be applied to a semiconductor wafer;

FIGS. 4A and 4B are cross-sections each showing a step of a modified example of the first embodiment;

FIGS. 5A to 5D are cross-sections each showing a manufacturing step of a semiconductor device according to the second embodiment;

FIGS. 6A to 6C are cross-sections each showing a brief structure of the semiconductor device according to the second embodiment;

FIG. 7 is a cross-section showing a brief structure of a semiconductor device according to the third embodiment;

FIGS. 8A to 8C are cross-sections each showing a manufacturing step of the semiconductor device shown in FIG. 7;

FIGS. 9A and 9B are a plan view and a cross-section each showing a modified example of the third embodiment;

FIGS. 10A and 10B are diagrams showing application states of inkjet on the semiconductor shown in FIGS. 9A and 9B;

FIG. 11 is a cross-section showing a brief structure of a semiconductor device according to the fourth embodiment;

FIGS. 12A to 12C are cross-sections each showing a manufacturing step of a semiconductor device according to the fifth embodiment; and

FIGS. 13A to 13C are cross-sections each showing a manufacturing step of a semiconductor device according to the sixth embodiment.

### DETAILED DESCRIPTION OF THE INVENTION

Semiconductor devices and their manufacturing methods according to embodiments will now be described with reference to drawings.

### First Embodiment

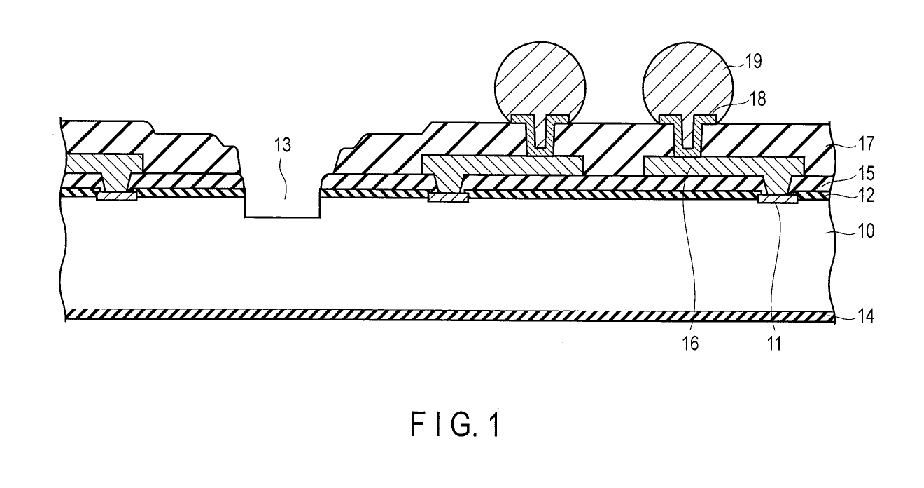

FIG. 1 is a cross-section showing a brief structure of a semiconductor device according to the first embodiment of the present invention. This embodiment relates to, in particular, a wafer level package (WLP) of CSP, and further to an example of WLP which comprises a protective film, a rewiring film and a rewiring sealing film, and a solder terminal formed on a under-bump-metal (UBM) of a land opening.

In this figure, an Si wafer (semiconductor substrate) 10 is shown on which electronic circuits are formed on each chip. On an uppermost layer of the wafer 10, an aluminum connection pad 11 and a passivation film 12 of silicon nitride, silicon oxide or the like is formed. A central portion of the connection pad 11 is exposed via an opening made in the passivation film 12. Further, a dicing line 13 is formed in a surface portion of the wafer 10 to divide the wafer 10 into a plurality of chips.

An insulative protective film 15 of polyimide or the like is formed on the wafer 10 with the exclusion of a portion for the dicing line 13. The protective film 15 has an opening on the connection pad 11. A rewiring line 16 of Cu or the like connected to the connection pad 11 is formed on the protective film 15.

A rewiring sealing film 17 is formed on the protective film 15 to cover the rewiring line 16. The rewiring sealing film 17 has an opening to connect to the rewiring line 16. At the opening of the rewiring sealing film 17, a solder terminal 19 of a solder ball is formed via a UBM 18. Here, the rewiring sealing film 17 includes a thin portion near the dicing line.

The protective film 15 and the rewiring sealing film 17 are not formed in an outer peripheral portion (edge portion) of the wafer 10, which is not illustrated in the figure. Note that the figure also shows a rear surface protection film 14 formed on the rear surface of the wafer 10 formed by inkjet. The rear surface protection 14 may be formed as necessity.

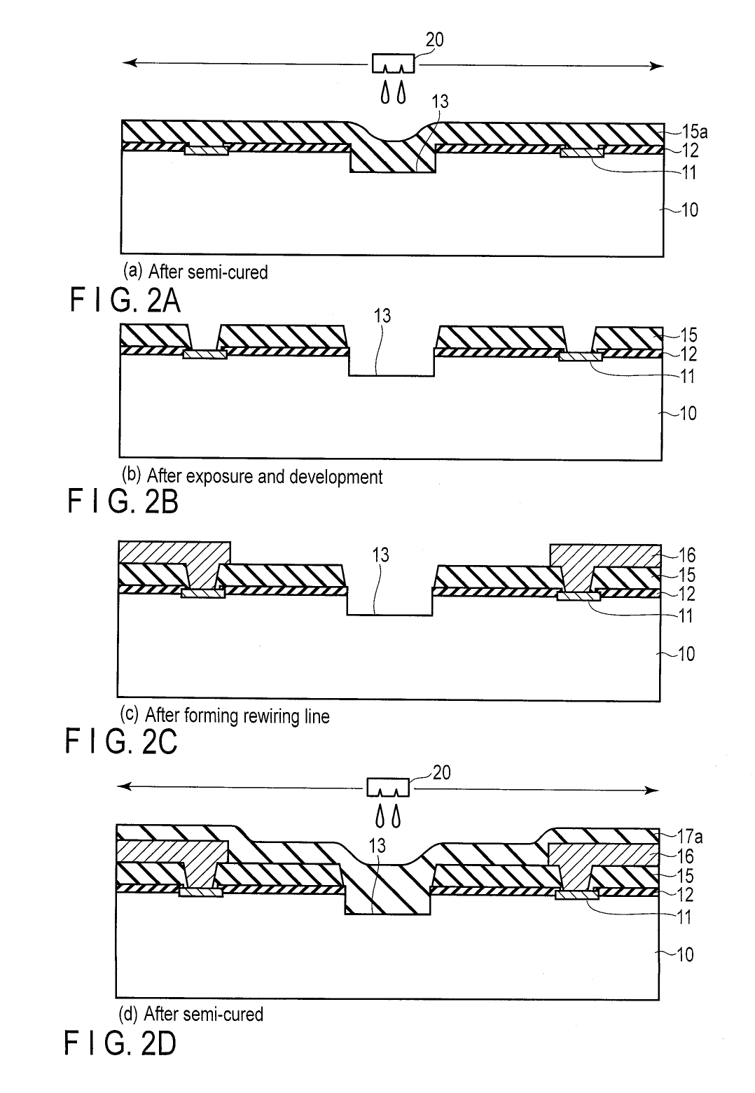

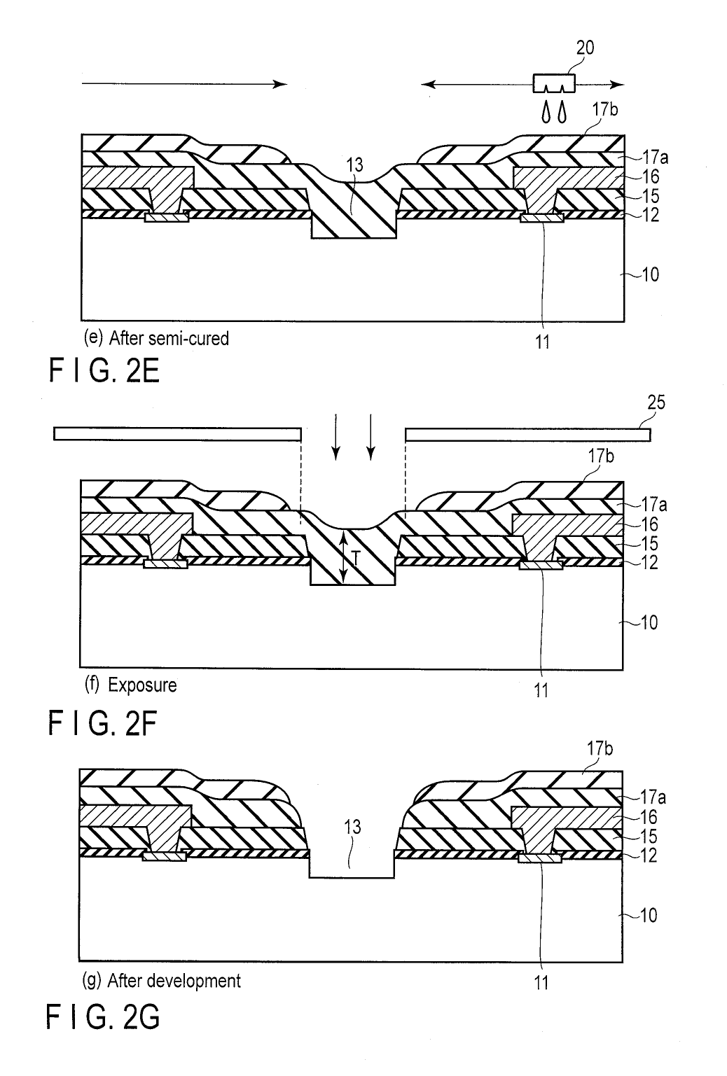

Next, a method of manufacturing a semiconductor device shown in FIG. 1 will now be described with reference to FIGS. 2A to 2G showing cross sectional views of steps, and FIGS. 3A and 3B showing plan views. Note that FIGS. 2A and 2G show the left half of the device shown in FIG. 1, which includes a dicing line.

First, as shown in FIG. 2A, an insulative photosensitive resin film 15a is formed by inkjet on the semiconductor wafer 10 on which the connection pad 11 and the passivation film 12 are formed. That is, as shown in FIG. 3A, a liquid photosensitive resin material diluted by a solvent is discharged by fill-application onto an entire surface of the wafer 10. More specifically, a liquid photosensitive resin material is applied on the wafer 10 with the exclusion of its outer peripheral portion of, for example, 10 mm or less, preferably, 5 mm or less, or more preferably, 3 mm or less. The liquid photosensitive resin material is a material of a composition which becomes to function as an insulation film such as a protective film when a curing process such as heating is carried out. The photosensitive resin material is different from an ordinary photolithography resist which is to be eventually removed by peeling.

Here, the “fill-application” will be explained. The “fill-application” is to carry out application at uniform application amount. The inkjet technique entails such a drawback that when forming a film thereby, the thickness of the film may vary. This is because nozzles of each inkjet head differ in discharge characteristics and device characteristics. Further, the liquid material flows in complicated ways in the process of fusing droplets together after discharging, which adversely affects the application of the material. Therefore, in order to suppress the above-described variation, the discharge amount, the discharge pattern and the like are finely adjusted in some cases in inkjet devices. The “fill-application” means the application of a material at substantially uniform amount including such a case where such adjustments are carried out.

To summarize, the terms, “uniform application” and “fill-application” explained in the specification include not only completely uniform application but also substantially uniform application.

When applying the resin material to the wafer 10, a wafer edge correction (, in which adjustment of the discharge amount is partially carried out in the wafer edge portion,) may be carried out as measures against “coffee stains” created in a wafer edge. Note that a “coffee stain” means a prominence formed in an edge portion of an applied section, and when the material is applied thickly, coffee stains are created remarkably. When a coffee stain is formed in a photosensitive material, the material may partially remain at the portion of the coffee stain due to lack of exposure or curing failure may occur. These drawbacks need to be avoided. As the photosensitive resin material, insulating photosensitive resins such as polyimide resin, polybenzoxide (PBO), phenol resin, epoxy resin and BCB can be used. The photosensitive resin used here is of a positive type, in which an exposed portion is removed by development.

When applying the material to an entire surface except for the outer peripheral portion, the coating material can be prevented from finding its way around to the rear surface of the wafer. Further, an alignment mark formed on the wafer can be exposed from the insulating film. In the case of a non-transparent insulating film, the alignment mark can be recognized when it is exposed. In the case of a transparent insulating film, the visibility of the mark can be improved when exposed. In any case, the alignment process necessary for the later manufacturing steps can be carried out accurately. It is also possible to expose a region of chips which are beyond the limits of guarantee or dicing line located near the outer peripheral portion of the wafer, and use an alignment mark in those area, or use the exposed dicing line or such other exposed structure for alignment.

Note that in order to reduce the uncoated area of the outer peripheral portion to meet the requirement for improving the efficient utilization of wafers, the width of the uncoated outer peripheral portion may be increased in the vicinity of the alignment mark using area compared to other portion.

Next, processing of vacuum drying, pre-baking and cooling is carried out to temporarily form a photosensitive resin film 15a in a semi-cured state. Note that the drying process is not limited to this, but some other method can be employed, for example, pressure reduction may be omitted. The thickness of the film in the semi-cured state is, for example, 6 μm.

Subsequently, as shown in FIG. 2B, portions corresponding to the dicing line 13 and the connection pad 11 are opened by exposure and development process using photolithography with a reticle (not shown). After that, the photosensitive resin film 15a is thermally cured, and thus a protective film 15 having a thickness of 9 μm (after contraction) is formed. That is, with the exclusion of the outer peripheral portion of the wafer 10, the photosensitive organic resin film 15a formed by inkjet, and then a pattern of dicing lines and openings, etc. is formed by photolithography.

Next, a plating resist film (not shown) is formed on the protective film 15, and thereafter, a rewiring resist pattern (reversal pattern for rewiring) is formed by photolithography. Subsequently, as shown in FIG. 2C, a rewiring portion 16 is selectively formed by plating, and then the resist is removed. A layer of Ti, Cu or the like may be formed in advance by sputtering as a foundation layer of the plating.

Next, a rewiring sealing film 17 of a photosensitive resin is formed on the protective film 15 by inkjet. More specifically, as shown in FIG. 2D, positive-type photosensitive polyimide is discharged by fill-application onto an entire surface as the first-time application from at least one inkjet head 20. Here, as in the case of forming the protective film 15, the material is applied to the wafer 10 with the exclusion of its outer peripheral portion of, for example, 10 mm or less, preferably, 5 mm or less, or more preferably, 3 mm or less as shown in FIG. 3A. Further, the wafer edge correction and exposure of the alignment mark are carried out as in the case of forming the protective film 15.

Subsequently, processing of vacuum drying, prebaking and cooling is carried out to form, as a first layer, a photosensitive resin film 17a having a thickness of, for example, 4.5 μm in a semi-cured state.

Next, as shown in FIG. 2E, positive-type photosensitive polyimide is discharged by fill-application onto the region with the exclusion of the dicing line 13 as the second-time application from the inkjet head 20. That is, as shown in FIG. 3B, the resin material is applied to the wafer 10 with the exclusion of the regions of the outer peripheral portion and the dicing line 13. Here, the material is applied to the central portion of the chip in its entirety. Then, processing of vacuum drying, prebaking and cooling is carried out to form, as a second layer, a photosensitive resin film 17b having a thickness of, for example, 4.5 μm in a semi-cured state.

Note that the “application to the region with the exclusion of the dicing line” means that the material is applied to the region with the exclusion of a part or the entirety of the dicing line 13 and its neighboring area. But depending on the application accuracy, dripping and flow (oozing out), a certain amount of resin film may be formed on the dicing line 13 or an opened state may be created.

With the above-described processing, an intermediate laminate film of two layers in a semi-cured state is temporarily formed. Note that a portion of the intermediate laminate film where a dicing line is to be formed is recessed. This is only presented as a typical example, but a similar structure may be formed of a single layer or three or more layers. Further, the order of formation of the first layer and second layer may be reversed. Further, the drying process can be carried out in such a manner that vacuum drying is carried out on each of the first and second layers, and then the layers are altogether subjected to the prebaking and cooling, or may be in some other manner. Furthermore, an opening may be formed also in the first layer of the intermediate lamination film to form an opening in the portion of the intermediate lamination film, which is for the dicing line.

Note that since the dicing line 13 is formed in the second layer by opening, a chip edge correction may be carried out as measures against coffee stains created in dicing line boundaries (edges) between chips when applying the resin material to the wafer 10 by inkjet.

The reason why the vacuum drying is employed is to suppress flow (smearing) of the liquid resin diluted with a solvent to be applied. The flow can be reduced by drying in short time at reduced pressure. Therefore, this is effective as the coffee stain measurements similar to the wafer edge correction and the chip edge correction.

Next, as shown in FIG. 2F, the portion for the dicing line 13 and land portion for electrodes for external connection are irradiated with exposure light with lithography using a reticle 25. Note that FIG. 2F shows only exposure of the dicing line 13.

Next, development is carried out, thereby forming an opening in the first layer of the intermediate lamination film, that is, a resin film 17a as shown in FIG. 2G. Subsequently, thermal curing is carried out to form the rewiring sealing film 17 in which resin films 17a and 17b are integrated. The thickness of the rewiring sealing film 17 (after contraction) is, for example, 6 μm.

That is, as to the rewiring sealing film 17, if films 17a and 17b are regarded as one resin film, a rough pattern is formed by inkjet and then an accurate pattern is formed by exposure in the dicing line 13. The contact opening is formed by accurate patterning using exposure.

Here, the portion for the dicing line 13 is formed into a recess and the thickness thereof is relatively less. Therefore, it can be patterned sufficiently by exposure using photolithography even with high accuracy. That is, in the recess roughly formed by inkjet, the opening can be formed with high accuracy by exposure.

Note that an opening for the dicing line 13 is formed in order to avoid the decrease in reliability in the dicing. To explain, when cutting with a blade, a physical force is applied and a cross section of the cut becomes coarse, thereby making it easy for the resin film 17 to peel off. But when the dicing line 13 is opened, these drawbacks can be suppressed. Further, when the dicing line 13 is opened, the amount of wearing of the blade, which occurs by dicing a substrate into pieces, can be reduced. Furthermore, the alignment mark formed in a dicing line region can be recognized, or the visibility can be improved.

Thereafter, an UBM is formed and a solder ball is mounted, and thus the structure shown in FIG. 1 is completed. Then, the rear surface is polished and the structured is diced into a plurality of chips. The UBM 18 may be formed by, for example, the following method. That is, a resist pattern is formed by photolithography in an area excluding the opening of the rewiring sealing film 17 or its surrounding area. Subsequently, the UBM 18 of Cu or the like is formed by electrolytic plating in the opened portion of the resist pattern and thereafter the resist pattern is removed. A Ti or Cu layer may be formed in advance by sputtering as a foundation layer of the plating.

As described above, in this embodiment, the rewiring sealing film 17 is formed of two resin films 17a and 17b by inkjet, and on the dicing line, a recess is formed in the resin films. With this structure, the opening of the dicing line 13 can be formed with high accuracy by photolithography. Further, the photosensitive resin is applied by inkjet, and thus the waste of the expensive photosensitive resin material, which would occur when a spin coat technique is employed, can be avoided.

Further, it is possible to avoid the coating material from finding its way around to the rear surface of the wafer, and therefore edge rinsing or back rinsing, which would be required in the spin-coating is not necessary, thus simplifying the process. Further, the embodiment has another advantage that unlike spin-coating, the variation in film thickness caused by centrifugal force due to rotation or wind pressure does not occur.

In the case of a thick resin film, the solvent remains inside even when the surface is dry, which easily causes the problem of a low development efficiency resulting from the difference in dryness between the surface and inside of the film. As a solution to this, the rewiring sealing film 17 can be formed not by one whole application at once but by two or more times of applications of stack coatings to make each of the resin films thinner. In this manner, these resin films can be dried isotropically. Thus, the above-mentioned problem can be lightened, and the development quality can be more stabilized.

The relationship between the exposure depth and the resin film formed in a dicing line will now be described.

The upper limit of the depth exposable with respect to a positive-type polyimide (for forming the protective film or rewiring sealing film or the like) by an ordinary exposure device (in one exposure) used in photolithography is 17 to 20 μm. Note that it may be possible to perform two or more exposures repeatedly, but this method lowers the productivity and also heats the lens, which deteriorates the exposure accuracy; therefore this method is not preferable.

In spin-coating, the applied liquid is spread by centrifugal force, and therefore if there is a trench, for example, a dicing line or the like, the trench is filled with the resin liquid basically. Therefore, if the thickness exceeds the exposable depth, the exposure by photolithography is no longer effective.

More specifically, when, for example, the trench of the dicing line groove is formed to have a depth of 6 μm, the protective film 6 to have a thickness of 6 μm, the intermediate lamination film of the rewiring sealing film to have a thickness of 9 to 12 μm, and also the trench is completely filled by spin-coating, the total thickness will be 21 to 24 μm. In this case, exposure cannot reach the bottom of the resin on the dicing line 13, and a problem arises that the resin on the dicing line 13 cannot be completely removed.

By contrast, with the coating by inkjet in this embodiment, the recess portion is formed above the dicing line 13 to lessen the thickness of the resin, the exposure can be fully carried out. As shown in FIG. 2F, when the resin film on the dicing line 13 is thinner than the case of spin-coating, and also a thickness T of the resin is within the exposure depth, a desired resolution can be achieved by photolithography. Note that there may be some cases where exposure is not completely done to the bottom of the dicing line due to, for example, a thick resin film formed thereon. Even in such a case, it is more preferable that the resin portion retaining on the bottom be reduced in order to suppress wearing of blade and secure the reliability.

Further, it is alternatively possible to employ, in place of the positive-type, a negative-type photosensitive resin, whose photosensitive depth is deeper than that of the positive-type. Note that as compared to the positive-type in which the solubility increases by exposure, the negative-type in which the solubility decreases by exposure is inferior in terms of peeling-off properties, development quality, accuracy and the like. Also, in the case of the negative-type, a solvent made of cyclopentanone, cyclohexanone or the like as a basic component, may be used for development. But the use of these solvents with toxicity is not preferable from viewpoints of an influence on the operator' health and environment conservation.

### Modification 1 of First Embodiment

In the first embodiment, the dicing line is formed in the protective film 15 and the rewiring sealing film 17 by photolithography. But a pattern on the protective film 15 and the rewiring sealing film 17 may be formed by inkjet without any trouble.

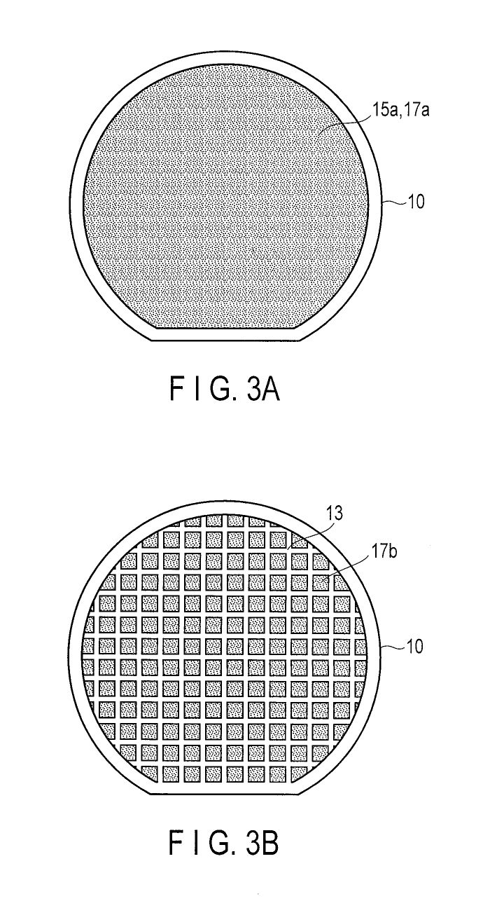

For example, as shown in FIG. 4A, for the formation of the rewiring sealing film 17, the photosensitive resin film 17a is formed by inkjet with the exclusion of the dicing line 13. As for the dicing line, such a high processing accuracy is not required as compared to the connection pad or contact. Therefore, although depending on coating conditions such as the viscosity of the resin material and the amount of application, the pattern can be formed by inkjet.

That is, as to the resin film 17a, for the dicing line, which does not require high accuracy, the pattern is formed by inkjet, whereas the opening for the contact, which requires a high accuracy, the pattern is formed by exposure with photolithography.

Note that even when the opening is made in the dicing line portion by inkjet, dripping may occur.

Therefore, during an exposure in photolithography (formation of a pad, land or the like), the exposure to development should preferably be carried out also on the dicing line 13 as shown in FIG. 4B so that the photosensitive resin film 17a will not remain in the dicing line 13.

### Modification 2 of First Embodiment

In the first embodiment, when an intermediate lamination film consisting of a plurality of layers, the case of two or three layers is described as a typical example. But in any case, the number of lamination layers may differ from one another. Further, in the case of “fill-application”, the film may be formed in a different pattern, in which the material is applied while avoiding the dicing line when necessary, for example. Further, the layers may be formed to have different thicknesses or viscosities.

In the application by inkjet, the influence of dripping and flow (oozing out) of the resin material differ depending on the viscosity of the liquid resin diluted with a solvent while being discharged, nozzle diameter, film thickness and the like. In order to raise the throughput for a better economic efficiency, it is effective to apply the material with a larger diameter of nozzle opening, a larger droplet size, and a lower viscosity. On the other hand, in order to accurately form the recess portion in the dicing line portion or some other patterns, it is effective to suppresses the occurrence of dripping and flow (oozing out) as much as possible with a smaller nozzle diameter, a smaller droplet, and a higher viscosity.

Therefore, in the case of, for example, pattern application (or offset application later described in the third embodiment), any one of the following methods may be employed, that is, an inkjet head having a smaller nozzle diameter is used as compared to the case of fill-application, the amount of droplet discharged is further decreased, and a resin material of a higher viscosity is discharged. With these methods, the resin film applied for fill-application can be formed at high throughput and low cost, and as for pattern application or offset application, required accuracy is secured. In this manner, an economical manufacturing can be carried out as a whole. Note that in the case of pattern application (or offset application), an inkjet device different from that used for fill-application may be used.

In the first embodiment, using the pattern forming function of inkjet, a recess or opening is formed in the dicing line portion of the rewiring sealing film 17, and then high-accuracy pattern formation is carried out by photolithography. The above-described method can be similarly applied to the formation of the protective film 15 or other insulating resin films.

In the meantime, in the first embodiment and modification 1 thereof, the section of fill-application of the resin by inkjet can be substituted by spin-coating. But in this case, it is necessary to carry out edge-rinsing of the outer peripheral portion, and to increase the amount of the coating material, etc.

This embodiment is discussed mainly in connection with the formation of a recess and opening in the dicing line portion as a typical example. But the invention can be similarly applied to the case where a recess or opening should be made in a photosensitive resin film formed on a wafer.

When, for example, the photosensitive resin is applied while avoiding the dicing line and the like by utilizing the function of inkjet, the area subject to a resin to be removed by exposure and development is decreased, and the thickness of the film is controlled within a necessary range. Thus, the amount of use of the photosensitive resin material, which is expensive, can be reduced.

This embodiment is described in connection with the case where a solder ball is mounted on a UBM as an electrode for external connection as a typical example. But any type of electrode for external connection, including a solder bump, columnar electrode and copper pillar, can be used as an electrode for external connection regardless of its shape. It is also possible to provide an electrode for external connection directly above the connection pad without providing a rewiring line. These points are common in the second and other embodiments later described.

### Second Embodiment

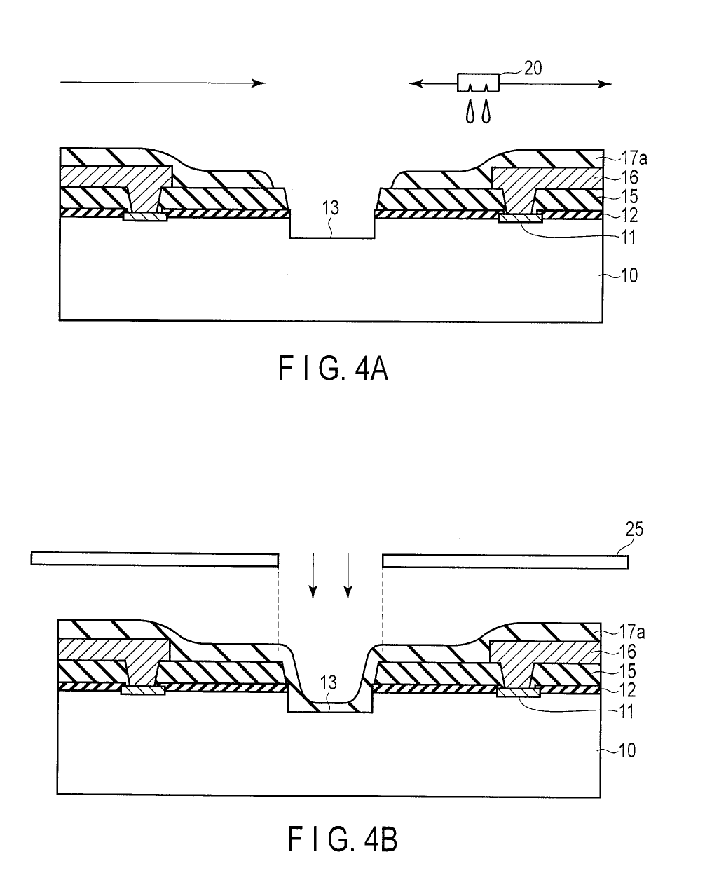

FIGS. 5A to 5D are cross-sections each showing a manufacturing step of a semiconductor device according to the second embodiment. The same structural parts as those shown in FIG. 1 and FIGS. 2A to 2G will be designated by the same reference numbers, and the detailed descriptions thereof will be omitted.

This embodiment is an example of WLP in which a protective film underneath a solder terminal is formed thickly. This embodiment is different from the first embodiment described above in that the present invention is applied not only to the second layer, that is, the rewiring sealing film, but also to the first layer, that is, the protective film.

In this embodiment, an intermediate lamination film of a photosensitive resin is formed to have a thickness of 18 μm by inkjet in order to form the first layer, the protective film.

More specifically, as shown in FIG. 5A, positive-type photosensitive polyimide is discharged by fill-application onto an entire surface as the first-time application from the inkjet head 20. Next, processing of vacuum drying, pre-baking and cooling is carried out to form, the first layer, a photosensitive resin film 15a to have a thickness of 9 μm in a semi-cured state.

Next, as shown in FIG. 5B, positive-type photosensitive polyimide is selectively applied as the second application from the inkjet head 20 with the exclusion of the areas around the dicing line and the connection pad. Then, processing of vacuum drying, pre-baking and cooling is carried out to form, the second layer, a photosensitive resin film 15b to have a thickness of 9 μm. Thus, an intermediate lamination film of two layers is provided.

Note that in both applications of the photosensitive resin films 15a and 15b, the outer peripheral portion of the wafer 10 is excluded as in the case of the first embodiment provided above.

Next, as shown in FIG. 5C, the portion for a dicing line 13 and the portion above a connection pad are irradiated with exposure light with photolithography using a reticle 25. Here, the region in which the pattern should be formed with photolithography is only the photosensitive resin film 15a, and therefore the portion of the resin is made thin. Thus, exposure can be carried out with high accuracy.

Next, as shown in FIG. 5D, development and thermal curing are carried out to form the dicing line 13 and a protective film 15 with an opening formed in the connection pad portion.

From this step on, a rewiring line 16 is formed, and a rewiring sealing film 17 is formed by inkjet, followed by the formation of a UMB 18 and a solder terminal 19, thus completing a WLP. The other points are similar to those of the first embodiment and its modifications.

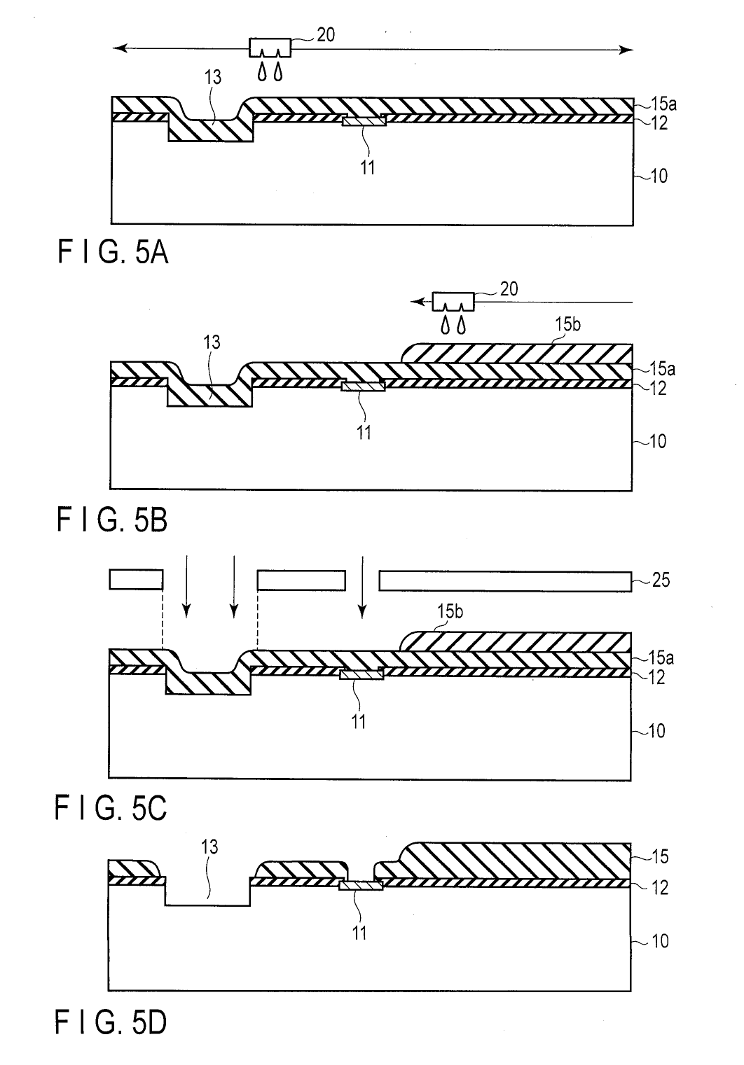

As examples of the semiconductor device thus manufactured, FIG. 6A shows an application to a peripheral pad portion, FIG. 6B shows an application to a central pad portion, and FIG. 6C shows an application to an array portion.

In FIG. 6A, the portions of the film for the dicing line 13 and the region around the chip are formed thin, whereas the central portion of the chip is formed thickly. The embodiment is not limited to this, but in the case of the center pad (where the pad is at the central portion of the chip), the portions for the dicing line 13 and the central portion can be formed thin as shown in FIG. 6B. Further, as shown in FIG. 6C, when pads are formed in array, the regions of the film for the respective pads can be individually made thin.

According to this embodiment, the photosensitive resin film is formed by inkjet, and thus the resin film can be formed to have a projection-and-recess shape including a thick portion and a thin portion (and also an intermediate portion when necessary), etc. With this structure, if the protective film underneath the solder terminal is formed thickly, the portions of the resin which correspond to the dicing line 13 and the opening for the connection pad 12 can be formed thin. Therefore, as long as the total thickness is within the exposure depth, exposure by photolithography can be employed, and thus a highly accurate pattern formation can be achieved. Further, as the underlying portion of the section where the solder terminal 19 is to be formed, a thick protective film can be formed.

Note when the protective film (PI layer/buffer coating layer) underneath the solder terminal 19 is formed thickly, the concentration of stress can be reduced by dispersion due to a buffer layer-like effect, and therefore the reliability of implementation in temperature cycle, shock when dropped, etc. can be improved. Further, when the rewiring line 16 is bent not only within a planar direction (XY-plane), but also in a longitudinal direction (Z-axis), a further stress-releasing effect can be expected. Here, it is preferable that the vertical bending should be a mild curvature.

In some devices, a decrease in damage to device, improvement in transmission performance of high-frequency electrical signal, etc., can be expected as an additional effect. Further, improvements in electrical characteristics and moisture resistant reliability can be expected.

### Third Embodiment

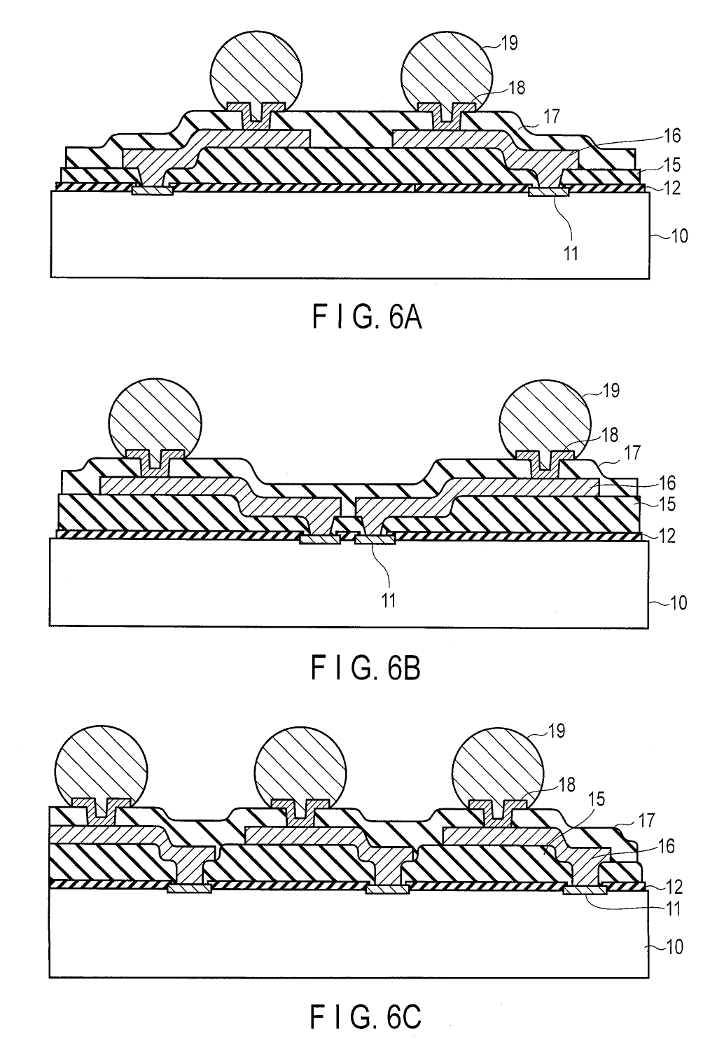

FIG. 7 is a cross-section showing a brief structure of a semiconductor device according to the third embodiment. The same structural parts as those shown in FIG. 1 will be designated by the same reference numbers, and the detailed descriptions thereof will be omitted.

This embodiment is an example of WLP comprising a multilayer wiring portion.

A connection pad 11 and passivation film 12 are formed on an Si wafer 10, and a protective film 15 is formed on an entire surface of the wafer with the exclusion of a portion for a dicing line 13. The protective film 15 has an opening in a portion above the connection pad 11. On the protective film 15, a rewiring line 16 of Cu or the like, which is connected to the connection pad 11, is formed.

A rewiring sealing film 17 is formed on the insulating film so as to cover the rewiring line 16. The rewiring sealing film 17 has an opening to connect to the rewiring line 16. Here, the surface of the rewiring sealing film 17 is formed substantially flat regardless of the irregularities of the underlying rewiring line 16, or to have a moderate projection-and-recess configuration.

An upper-layer rewiring line 36 of Cu or the like, connected to the rewiring line 16 is formed on the rewiring sealing film 17. An upper rewiring sealing film 37 is formed on the rewiring sealing film 17 so as to cover the upper-layer rewiring line 36. The upper rewiring sealing film 37 has an opening to connect to the upper-layer rewiring line 36. At the opening of the upper-layer rewiring sealing film 37, a solder terminal 19 of a solder ball is formed via a UBM 18.

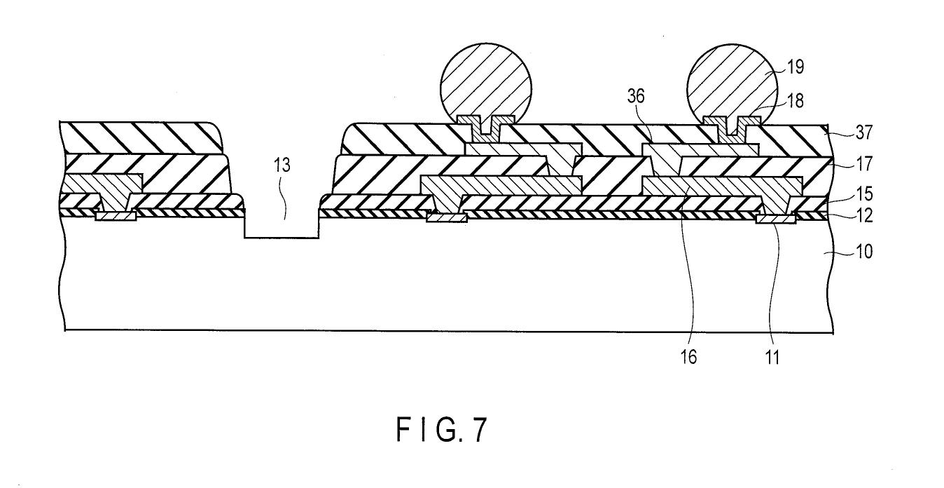

FIGS. 8A to 8C show the right half of the device shown in FIG. 7, which does not include a dicing line 13.

First, as shown in FIG. 8A, the connection pad 11, the passivation film 12, the protective film having a thickness of 6 μm, and the rewiring line 16 are formed on the Si wafer 10. After that, a photosensitive resin film 17a is applied thereon by inkjet to form the rewiring sealing film 17.

Here, when there are, for example, recesses and projections formed on the wafer 10 due to the rewiring line and the like, the amount of the photosensitive resin applied by inkjet is adjusted to be more the recessed regions than in the projecting regions, thereby to offset (that is, to the recessed and projecting regions or reduce the recessed and projecting regions to be more moderate).

The liquid material applied by inkjet contracts as the solvent volatilizes and moisture and the like evaporate through a drying and curing step. If there are recesses and projections, and a liquid resin is formed more thickly in the recesses than in the projections, the amount of contraction at the recesses is greater than that at the projections. Therefore, even if the surface is in a flat condition just after the application, still recesses and projections are formed eventually on the substrate on which the resin film is formed.

In consideration of the influence by the resin contraction mentioned above (by back calculating), the application may be carried out to offset. Here, since it is not easy to accurately predict the result of contraction, a trial sample may be formed to confirm the result. In the trial sample, the wafer may be divided into several regions, where different conditions are assigned in terms of amount of application, pattern, etc., thus making it possible to perform trials and checking efficiently.

In order to apply a material non-uniformly, the amount of application should be varied partially. Further, the photosensitive resin should be applied to the wafer 10 with the exclusion of its outer peripheral portion as in the previous embodiments.

Subsequently, the photosensitive resin film 17a is exposed by photolithography and then developed and thermally cured. Thus, as shown in FIG. 8B, the rewiring sealing film 17 is formed to have openings in portions above to the dicing line (not shown) and the rewiring line 16.

Next, a resist pattern for rewiring line is formed on the rewiring sealing film 17 by photolithography as in the first embodiment aforementioned. Further, with a method of selectively forming a rewiring layer by plating, an upper-layer rewiring line 36 is formed.

Subsequently, as shown in FIG. 8C, a photosensitive resin film 37a is formed in a semi-cured state by inkjet in order to form the upper rewiring sealing film 37. The photosensitive resin film 37a may be formed as in the formation of the rewiring sealing film of the first embodiment. That is, the photosensitive resin film is thinned to form a recess in a portion corresponding to the dicing line, or the photosensitive resin film is applied while making an opening for the dicing line. Similarly, the outer peripheral portion of the wafer 10 is excluded from the application. Note that an upper-layer rewiring line and an upper-layer rewiring sealing film may be referred to generally a rewiring line and a rewiring sealing film.

Next, the dicing line 13 and contact opening are formed by photolithography, and then the photosensitive resin film 37a is developed and thermally cured to form the upper rewiring sealing film 37.

Thereafter, an UBM 18 is formed and also a solder terminal 19 is formed from a solder ball as in the first embodiment, and thus the structure shown in FIG. 7 is obtained. The other points are similar to those of the first embodiment and its modifications.

According to this embodiment, the rewiring sealing film 17 is formed by inkjet, and thus the projections and recesses of the rewiring sealing film 17 can be moderated. The upper-layer wiring line can be formed with highly accuracy and also the reliability can be improved.

### Modification of Third Embodiment

Not only in the case of multi-layered wiring, it is effective to partially vary the amount of application depending on the wiring pattern of the underlying portion and the like.

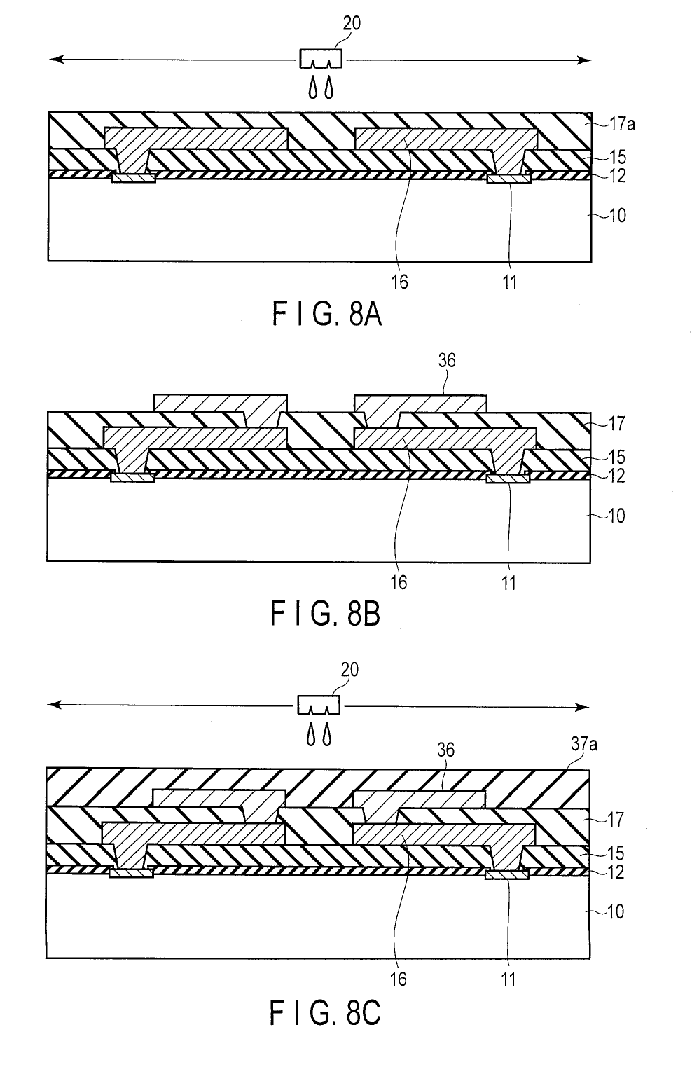

FIGS. 9A and 9B show an example in which there is a common signal line in rewiring line in the first embodiment. FIG. 9A is a plan view, whereas FIG. 9B is a cross-section thereof. As shown in these figures, in the rewiring line of WLP, a wiring line 41 functioning as a signal line and a wiring line 42 functioning as a common signal line usually may differ greatly from each other in shape.

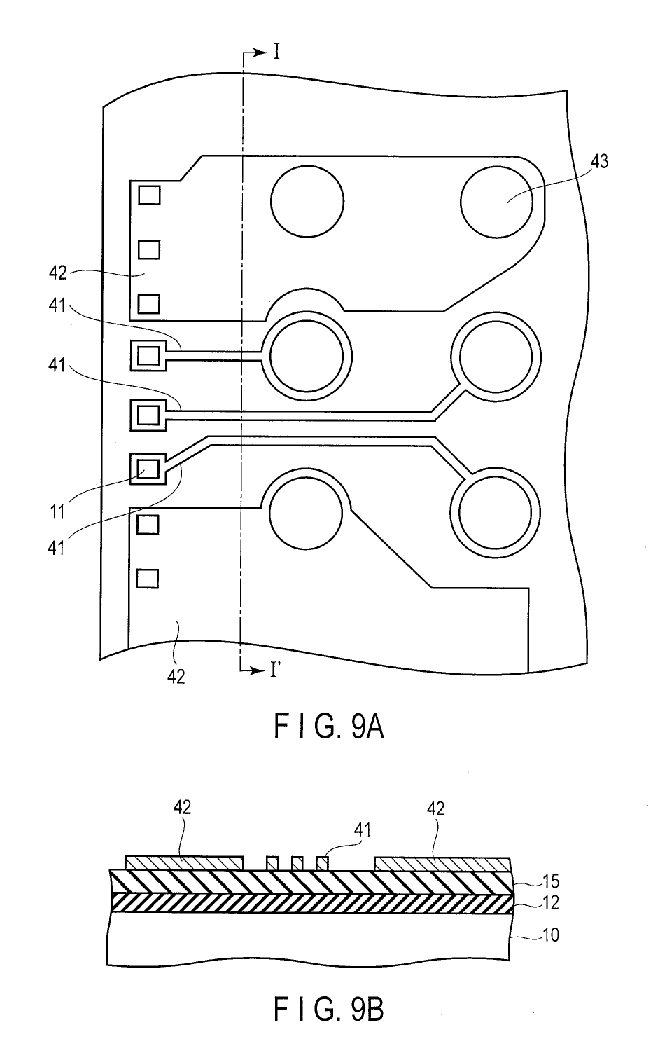

When the common signal wiring line 42 for a ground is formed wide, the thickness may vary partially in fill-application of a resin by inkjet. For example, as shown in FIG. 10A, there are some cases where the thickness greatly differ between a portion above the common signal wiring line 42, where dripping does not occur very much, and a portion above the signal wiring line 41, where dripping occurs.

In the case, as shown in FIG. 10B, the application is carried out twice with the inkjet head as in the first and second embodiments, thereby making it possible to moderate irregularities. More specifically, the resin is discharged by fill-application onto an entire surface as the first-time application from the inkjet head to form a semi-cured film. After that, the resin is applied to a specific area in an appropriate amount as the second application from the inkjet head to form an intermediate lamination film. Then, the intermediate lamination film is cured. Here, it is preferable as in the third embodiment that the contracting portions due to the volatilization of the solvent, evaporation of moisture and the like should be considered. In order to carry out a better offset, the amount of application in the first time and the second time may be partially changed, or the viscosity of the coating may be adjusted.

With the above-described operations, the flatness of the surface of the resin film can be improved, which is advantageous to the following processing steps, and therefore a high reliability can be achieved. This advantageous point is particularly important when the width of the rewiring line or the distance between wiring lines is finely narrowed to, for example, 10 μm or less, electrodes for external connection are formed at high density, high-frequency signals are handled, etc.

This embodiment is described in connection with the case of irregularities of projections and recessed formed due to rewiring lines, as a typical example. However, the invention is not limited to this, but it can be applied similarly to such cases where projections and recesses are formed due to passive elements such as inductors and capacitive elements and some other structural components.

Further, by adjusting the amount of application, the dispersion in film thickness within a wafer surface created in the WLP manufacturing process can also be offset. For example, when a photosensitive resin material is developed using a method of rotating the wafer, a coaxial variation in film thickness occurs in the wafer (that is, the amount of reduction of developed film differs from one point to another within the wafer surface depending on the distance from the rotation center). In order to avoid this, back calculation should be performed based on the result of measurement in which the amount of reduction of developed film differs from one point to another within the surface, and thus the amount of application from the inkjet head can be adjusted to make the film thickness after the development as uniform as possible. In this manner, it is possible to form a resin film with more uniform thickness. For example, in a section where the reduction of film by development is less, the material is applied thin in advance, thus making it possible to prevent remainder after development. When the dispersion in film thickness after development is reduced, the dispersion in thickness after curing can be reduced as well. Thus, the yield of conforming product and reliability can be improved.

### Fourth Embodiment

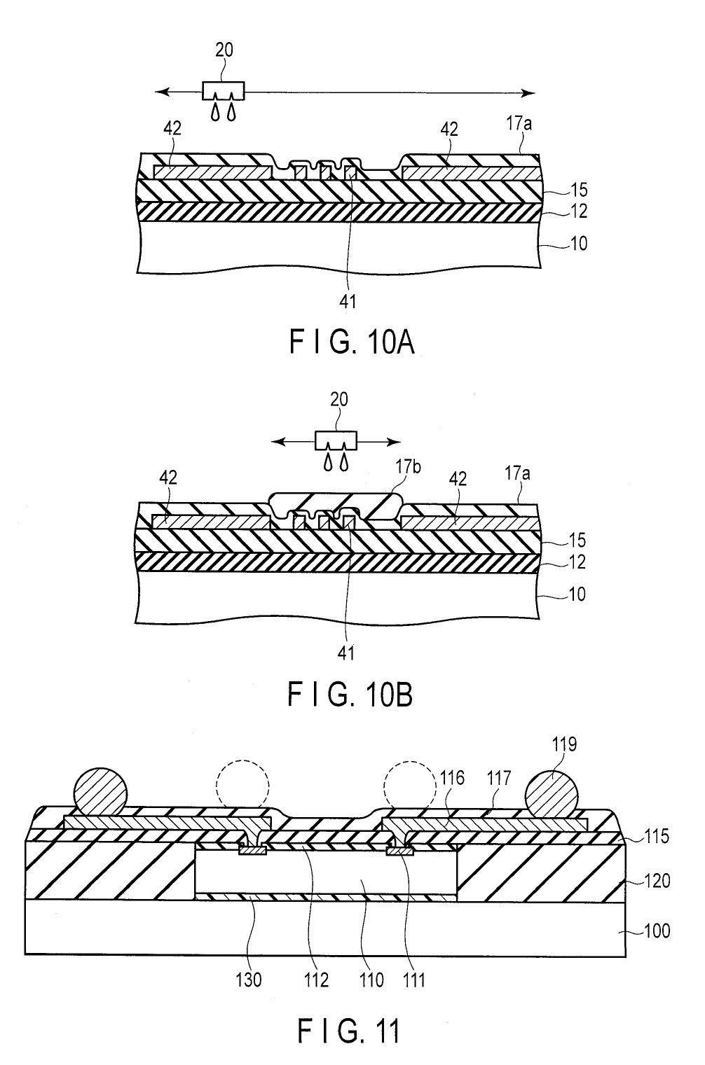

FIG. 11 is a cross-section showing a brief structure of a semiconductor device according to the fourth embodiment. This embodiment is an example in which the invention is applied to a fan-out wafer level package (Fan-out WLP).

The first embodiment is described in connection with the case where the resin film is formed on a semiconductor wafer as a typical example. The structure is not limited to this embodiment, but is similarly applicable to such a case where semiconductor chips are disposed at intervals therebtween, and a resin layer is formed on a resin-sealed wafer-shaped or square-shaped (panel shaped) semiconductor-chip buried substrate. Further, not only the first embodiment, but also the other embodiments described above can be similarly applied to the Fan-out WLP.

The Fan-out WLP is a package solution intermediate between the die level and wafer level. In the Fan-out WLP, a semiconductor wafer on which electronic circuits are formed is diced, and then cut-out microchips are buried in a new “artificial” wafer or panel (semiconductor-chip buried substrate). When burring, it is necessary to keep sufficient intervals between microchips for fan-out rewiring layers.

A semiconductor chip 110 is mounted on a support substrate 100. Side surfaces of the semiconductor chip 110 are buried with an insulating film 120 of a thermal curing resin or the like (a thermal curing resin such as an epoxy resin in which a reinforcing material such as a silica filler is dispersed, or a glass-cloth substrate in which a thermal curing resin such as an epoxy resin is impregnated, or a thermal curing material itself). The semiconductor chip 110 may be a bare chip or a package of WLP or the like. Note that the semiconductor chip 110 is adhered onto the support substrate 100 with, for example, an adhesive layer 130.

On the uppermost layer of the semiconductor chip 110, a connection pad 111 and a passivation film 112 of silicon nitride, silicon oxide or the like can be formed. A central portion of the connection pad 111 is exposed via an opening made in the passivation film 112. Further, although not shown in the figure, dicing lines are made or exist just as a predetermined area on a surface portion of the support substrate 100 so as to separate the substrate into a plurality of chips. In some Fan-out WLPs, support substrate 100 is not utilized. In such case, semiconductor-chip buried substrate itself works as the support substrate.

A protective film 115 of a resin such as polyimide is formed so as to cover the semiconductor chip 110 and the insulating film 120 with the exclusion of portions for the dicing lines. The protective film 115 has an opening at a portion above the connection pad 111. On the protective film 115, a rewiring line 116 of Cu or the like, connected to the connection pad 111, is formed.

A rewiring sealing film 17 is formed on the protective film 15 to cover the rewiring line 16. At the opening of the rewiring sealing film 17, a solder terminal 19 of a solder ball is formed. Here, the rewiring sealing film 17 includes a thin portion near the dicing line.

Note that although not shown in the figure, the protective film 115 and rewiring sealing film 17 are not formed in the outer peripheral portion (edge) of the support substrate 100 (or the semiconductor-chip buried substrate).

A typical manufacturing method for the Fan-out WLP is as follows. That is, semiconductor chips as individual pieces are disposed at intervals on a supporting substrate having a shape similar to that of a semiconductor wafer or a large-size square shape, and a resin is applied thereon for sealing while forming rewiring lines. Then, the chips are separated. With this method, rewiring lines can be formed in a region broader than the chip region without using a relaying substrate (interposer).

With the above-described structure, regions for forming electrodes for external connections can be secured, semiconductor devices, which require numerous electrodes for external connections, can be manufactured economically and in small size. Note that basically, the support substrate is peel off from the package, but the support substrate may remain to be integrated. In some case, the support substrate is not utilized and the semiconductor-chip buried substrate itself may works as the support substrate.

A specific manufacturing method will now be described. As in the first embodiment, a photosensitive resin film is applied by inkjet by fill-application to an entire surface of the support substrate 100 on which the semiconductor chip 110 and the insulating film 120 are formed (or the semiconductor-chip buried substrate), with the exclusion of an outer peripheral portion. When applying the material to an entire surface expect for the outer peripheral portion (that is, exposing the portion), the coating material can be prevented from finding its way around to the rear surface of the substrate. Further, an alignment mark formed on the substrate can be exposed from the insulating film.

Next, processing of vacuum drying, pre-baking and cooling is carried out to temporarily form a photosensitive resin film in a semi-cured state. Subsequently, portions corresponding to the dicing line and the connection pad are opened by exposure and development process using photolithography with a reticle (not shown). After that, the photosensitive resin film is thermally cured, and thus a protective film 15 having a thickness of 6 μm (after contraction) is formed.

Next, a plating resist film (now shown) is formed on the protective film 15, and thereafter, a rewiring resist pattern (reversal pattern for rewiring) is formed by photolithography. Subsequently, a rewiring portion 16 is selectively formed by plating, and then the resist is removed.

Next, a rewiring sealing film 17 of a photosensitive resin is formed on the protective film 15 by inkjet. Here, as in the first embodiment described above, a positive-type photosensitive polyimide may be applied on an entire surface by fill-application as the first-time application and positive-type photosensitive polyimide is applied to the region excluding the dicing line as the second-time application by inkjet.

Next, the portion for the dicing line and land portion for electrodes for external connection are irradiated with exposure light with lithography using a reticle. Then, development is carried out, thereby forming, an opening in the first layer of the intermediate lamination film (resin film). Subsequently, thermal curing is carried out to form the rewiring sealing film 17 in which resin films are integrated.

Here, the portion for the dicing line is formed into a recess and the thickness thereof is relatively less. Therefore, it can be exposed sufficiently by exposure using photolithography even with high accuracy. That is, in the recess roughly formed by inkjet, the opening can be formed with high accuracy by exposure.

Thereafter, a solder ball is mounted, and thus the structure shown in FIG. 11 is completed. Here, a UBM (not shown) may be formed before the mount of the solder ball. Then, the structure is subjected to dicing or the like to separate into and obtaining a plurality of packages.

According to this embodiment, the photosensitive resin film for forming the protective film 115 is applied to the support substrate 10 (or the semiconductor-chip buried substrate) with the exclusion of its edge portion, and the portion corresponding to the dicing line is applied more thinly than the other portions. With this structure, an effect similar to that of the first embodiment can be obtained in the Fan-out WLP as well.

This embodiment is discussed mainly in connection with the formation of a recess and opening in the dicing line portion as a typical example. But the invention can be similarly applied to the case where a recess or opening should be made in a photosensitive resin film formed on the semiconductor-chip buried substrate.

### Fifth Embodiment

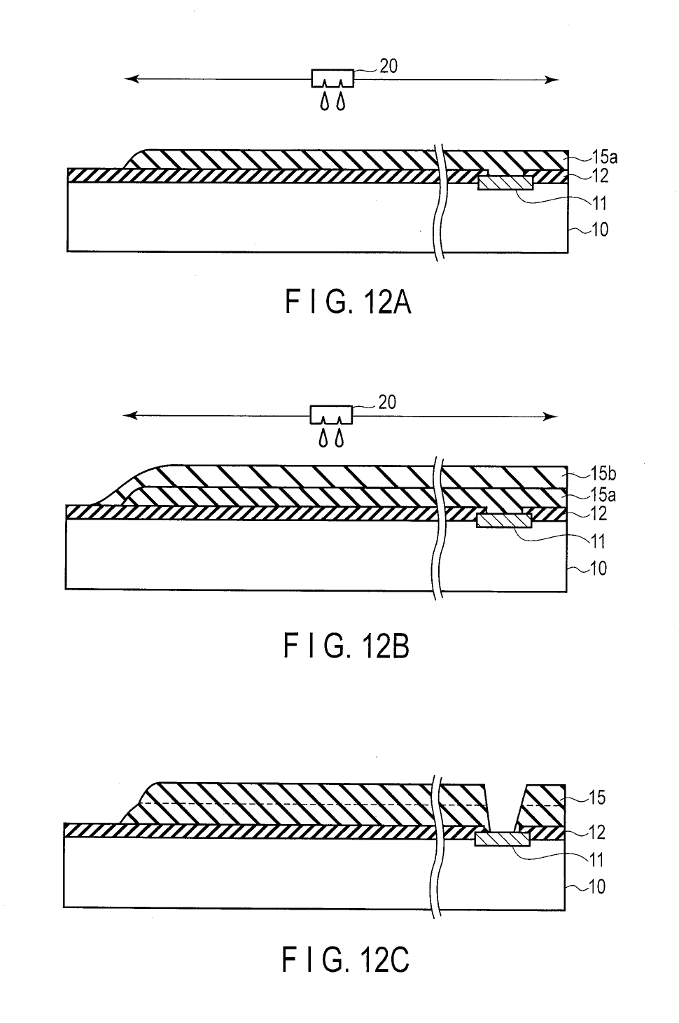

FIGS. 12A to 12C are cross-sections each showing a manufacturing step of a semiconductor device according to the fifth embodiment. The same structural parts as those shown in FIGS. 5A to 5D will be designated by the same reference numbers, and the detailed descriptions thereof will be omitted.

This embodiment aims to improve an edge portion when photosensitive resin films are stacked in layers.

When two or more photosensitive resin layers are applied one on another by inkjet, the following drawbacks are likely to occur in the end portion (edge portion).

(1) When the coating liquid for the second layer is applied to the location of the end portion of the first layer, it drips outwards (flow out) from the end portion of the first layer. Here, a step is created between the layer and the wafer, it is difficult to control the flow area of the coating liquid.

(2) If wafer edge correction is carried out as measures against coffee stains in the wafer edge, the correction may not be sufficient depending on the thickness or the film or the properties of the material.

Here, there has been an idea for avoiding drawback (1) above by setting the boundary of the application from the second layer on to a sufficiently inner side of the first layer. However, when the photosensitive resin is applied on a sufficiently inner side of the end portion so as not to allow the resin to flow out to the outside of the end portion, the area which cannot be utilized is increased, which does not meet the demand for effectively using the wafer to the limit of its outer peripheral portion.

This drawback multiplies as the number of lamination layers increases. Further, this drawback is common to the case where an intermediate lamination film is formed by forming a plurality of semi-cured resin layers, and the case where a plurality of resin films are stacked in layers.

Under these circumstances, according to this embodiment, a first photosensitive resin film 15a is applied as shown in FIG. 12A, and then a second photosensitive resin film 15b is applied over to the outer side of the first photosensitive resin film 15a as shown in FIG. 12B. Thus, the photosensitive resin film 15b is made to drip at the edge portion.

Subsequently, as shown in FIG. 12C, the unnecessary portion on the outer side, that is, the portion made from the dripping of the second photosensitive resin film 15b is removed by exposure and etching. When three or more photosensitive resin films are stacked, the above-described step is repeated.

Note that since exposing an outer peripheral portion of a discoid wafer with a stepper is not efficient, it is preferable that an exposure system which can apply UV to on an edge portion be employed.

As described above, the second photosensitive resin film 15b is formed over to the outside of the first photosensitive resin film 15a, and therefore the portion of the second photosensitive resin film 15b which is located outside the first photosensitive resin film 15a is removed by lithography. Thus, the accuracy of the edge portion of the photosensitive resin film 15 can be improved, thereby enhancing the use efficiency of the outer peripheral portion.

### Sixth Embodiment

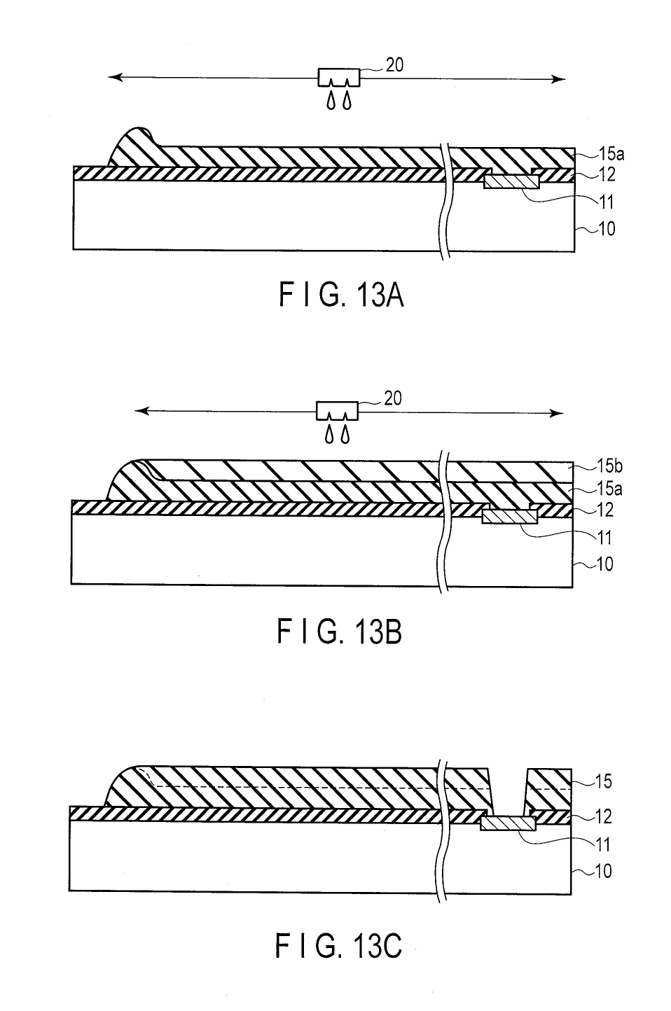

FIGS. 13A to 13C are cross-sections each showing a manufacturing step of a semiconductor device according to the sixth embodiment. The same structural parts as those shown in FIGS. 12A to 12C will be designated by the same reference numbers, and the detailed descriptions thereof will be omitted.

This embodiment provides another solution to drawbacks (1) and (2) above, in which upon edge correction in the application of the first layer (underlying layer), part of coffee stain is left and utilized as a bank. With this structure, the flow out of the material from the second layer (upper layer) on is prevented.

When the material for a photosensitive resin film is applied by inkjet, the first layer, that is, the first photosensitive resin film 15a is formed with a prominence in a border portion of the applied material in a wafer edge portion due to coffee stain, as shown in FIG. 13A. Note that edge correction may be carried out to allow coffee stain to be formed partially.

Subsequently, as shown in FIG. 13B, the second application is carried out by the inkjet head 20, to form the second photosensitive resin film 15b. Here, wafer edge correction is carried out to decrease the amount of ink discharged towards the end of the wafer to the minimum in the application of the material for the second photosensitive resin film 15b. This step is carried out so that, the upper layer, that is, the resin film 15b is formed on an inner side with respect to a top of the prominence of the lower layer, the resin film 15a.

Next, as shown in FIG. 13C, an opening for connecting to the connection pad is made by exposure and etching.

Thus, in this embodiment, when two or more layers are stacked to form a photosensitive resin film on a substrate, the lower layer, that is, the photosensitive resin film 15a is formed so that the outer edge portion thereof (the outer peripheral portion of the wafer or end portion of a piece of chip) has a “prominence”, and the upper layer, that is, the resin film 15b is formed on an inner side with respect to the top of the prominence of the lower layer, the photosensitive resin film 15a. With this structure, the upper layer, that is, the resin film 15b does not drip over to the outer side of the lower layer, that is, the photosensitive resin film 15a. Thus, the accuracy of the edge portion of the photosensitive resin film can be improved, thereby enhancing the use efficiency of the outer peripheral portion.

Note that the application of the method of this embodiment is not necessarily limited to the edge portion of a wafer. This method is applicable to the case where a similar drawback is involved, that is, a resin film is partially formed by stacking layers on a wafer, for example, a portion for the dicing line is opened while applying the material.

Further, the method of this embodiment is applicable similarly not only to the photosensitive resin film, but also to the case where a non-photoconductive resin film is formed by stacking layers, or a photosensitive resin film and a non-photoconductive resin film are stacked one on another.

### Common Modification 1

The present invention is not limited to the embodiments described above.

When a plurality of resin films are formed by inkjet in the manufacture of a semiconductor device, inkjet or photolithography may be selected for pattern formation as needed subject to the required accuracy for patterning.

More specifically, the formation of a resin film (first resin film) which requires high-accuracy patterning, includes, for example, formation of an opening in a protective film for a connection pad, formation of an opening in a rewiring sealing film for contact (opening for an electrode for external connection), and formation of a rewiring line using a resist. For such cases, the pattern forming method which uses the application of a photosensitive resin material by inkjet and the photolithography using a reticle is used. In this manner, a pattern can be formed with highly accuracy. Note that the formation of the first resin film may be done by applying the material to the entire surface excluding the outer peripheral portion by fill-application.

Meanwhile, for the formation of a resin film (second resin film) which does not require a relatively high accuracy, a liquid organic resin (, which may be non-photosensitive) is selectively applied by inkjet to form the pattern. Thus, a pattern which does not require a high accuracy can be formed at low cost.

As described above, according to patterns required for insulating films made of resin materials, inkjet or photolithography is selected to form a pattern. Therefore, a semiconductor device can be formed economically and accurately.

Besides those formed by inkjet in the above-provided embodiments, additional examples of the formation of the resin film which does not require a relatively high accuracy are as follows. That is, the formation of a resin film sealing the entire or part of the structure of a rewiring line, electrode for external connection, etc. (including sealing of the entire or part of a side surface of a columnar electrode), the formation of a side-surface protective film or a rear-surface protective film, etc.

Note that the second resin film can be formed by offsetting the projections and recessed in place of the pattern formation. Further, it is also possible to form a pattern by photolithography using reticle and using a photosensitive resin for the second resin film in addition to the pattern formation or offsetting by inkjet.

As already described, the influence of dripping, flow (oozing out) differs depending on the viscosity, nozzle diameter, film thickness and the like. In order to raise the throughput for a better economic efficiency, it is effective to apply the material with a larger nozzle diameter, a larger droplet size, and a lower viscosity. Therefore, for the formation of the second resin film by pattern formation or offsetting, one of the following methods may be employed, that is, an inkjet head of a smaller nozzle diameter is used, the amount of droplet discharged is reduced, or the resin material of a higher viscosity is discharged, as compared to the case where the first resin film is formed by fill-application. With this operation, the first resin film can be formed at high throughput and low cost, and the second resin film can be formed while keeping necessary accuracy. In this way, the economic efficiency as a whole can be improved. Note that the inkjet device for forming the second resin film may be different from the device for forming the first resin film.

### Common Modification 2

None of the embodiments indicates that a resist is applied to form a rewiring line or an electrode for external connection, such as the UBM or columnar electrode, but a resist film can be formed by inkjet instead of spin-coating. More specifically, here, a photosensitive organic resin material for resist is applied on an entire surface by inkjet, and then a resist pattern is formed by photolithography using a reticle. With this resist pattern, structures such as the rewiring line and external connection electrode are formed by electrolytic plating or the like. After that the organic resist film (resist pattern) should be removed.

Here, the resist should be applied to the wafer 10 with the exclusion of its outer peripheral portion, and the materials may be applied in twice or more in parts to form an intermediate lamination film as in the cases of the above-described embodiments. Other points of the above-described embodiments can be similarly applied. For forming an external-connection electrode such as a columnar electrode, a resist film having a thickness of more than 20 μm is required in many cases. To such cases, this invention can be effectively applied, including the formation of a thick film from an intermediate lamination film and the formation of a recess portion for a dicing line.

This invention is described as using an exposure using a reticle as a typical example of high-accuracy exposure. The invention is not limited to this, but photolithography using direct imaging may as well be employed as long as it has high accuracy.

Further, an insulating film or the like to seal the entire or part (including a side surface) of the structures of a rewiring line and an electrode for external connection, etc. can be formed by inkjet. In this case, the structures of the rewiring line or the electrode for external connection, etc. need to be formed at high accuracy, but the formation of the sealing film after formation of the structures does not require a similar accuracy. For this reason, the application by inkjet can be employed here to form this economically and efficiently.

For the formation of the rear-surface protective film and side-surface protective film, inkjet can be used. The formation of the rear-surface protective film may be carried out by applying the material to the surface in its entirety before dividing the wafer into individual pieces (FIG. 3A), or by applying liquid resin by inkjet to the surface excluding the portion for the dicing line (FIG. 3B). Alternatively, the rear-surface protective film and side-surface protective film may be formed by inkjet after the dicing step (after dividing into pieces).

By utilizing the inkjet function, a rough pattern for a trench, recess, through-hole, projection or the like may be formed to the insulating film.

The present invention is applicable, not only to the CSP processing steps, but also substantially all kinds of steps for forming organic resin layers to form an insulating layer on a semiconductor substrate. Further, the semiconductor substrate is not limited to an Si wafer, but other semiconductor materials, or further a compound semiconductor can be used.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

(Additional Note 1)

Further, the following structures are also desirable for the invention in addition to those recited in the claims.

(1) As to Claims 1 to 7, the step for forming the photosensitive resin film comprises a step of forming a resin film in a semi-cured state by discharging a liquid photoconductive resin material on the substrate from the inkjet head and drying the material by vacuum drying and prebaking.

(2) As to Claim 1, the step of forming an insulating photosensitive resin film by inkjet is a step for forming a resist film for the rewiring line, the UBM or the electrode for external connection. Further, the step of patterning the photosensitive resin film by photolithography is a step for forming a reversal pattern for the rewiring line, the UBM or the electrode for external connection on the resist film. Furthermore, the step for forming a rewiring line, UBM or an electrode for external connection is a step for forming the rewiring line, the UBM or the electrode for external connection on the reversal pattern by plating.

(3) As to (2), the step for forming the resist film comprises a step of forming an intermediate resin layer in a semi-cured state by applying a first photosensitive resin material to the substrate in an area excluding at least the edge portion, and thereafter subjecting it to vacuum-drying and prebaking, subsequently a step for forming a resin layer in a semi-cured state by applying a second photosensitive resin material in the area excluding the edge portion, and thereafter subjecting it to vacuum-drying and prebaking, thereby forming an intermediate lamination film, a step for patterning the intermediate lamination film by photolithography and a step for thermally curing the patterned intermediate lamination film to form an integrated insulating film.

(4) As to (3), the step for forming the intermediate resin layer comprises a step of discharging a liquid photosensitive resin material from the inkjet head uniformly onto one entire surface of the substrate with the exclusion of the edge portion for each of the resin layers constituting the intermediate lamination film, and performing edge correction which corrects an amount of discharge in a vicinity of the edge portion of the substrate.

(5) As to Claim 16, the step of forming the second organic resin film comprises a formation of a sealing film, a side-surface protective film or a rear-surface protective film.

(6) As to Claim 16, the application of an organic resin material by inkjet in the step of forming the first organic resin film comprises a step of discharging a liquid photosensitive resin material from the inkjet head uniformly onto one entire surface of the substrate with the exclusion of the edge portion, and performing edge correction which corrects an amount of discharge in a vicinity of the edge portion of the substrate.

(7) As to Claim 16, the step of forming the second resin film is carried out by one of the following ways, that is, a nozzle diameter of the inkjet head is reduced, the amount of discharge of droplets is reduced, and a viscosity while discharging is raised as compared to the case of forming the first resin film.

(8) A semiconductor device comprising a semiconductor substrate comprising a connection pad to electrically connect to a circuit element formed on a main surface, and an insulating film formed of a photosensitive resin on the substrate, and comprising an opening for connection with the connection pad, characterized in that the thickness of the insulating film in the vicinity of the opening is less than that of the other part.

(9) As to (8), the insulating film is formed by inkjet and the opening is formed by photolithography.

(Additional Note 2)

According to the present invention, the photosensitive resin is applied by inkjet, and then it is patterned using photolithography. In this matter, the wasteful use of the resin material can be reduced, and also the pattern can be formed with high accuracy.

To explain, by applying the photosensitive resin by inkjet, the wasteful loss of expensive photosensitive resin, which would occur with spin-coating, can be avoided. Further, the application of the resin in the peripheral portion of the substrate can be avoided, and also the resin film can be formed without occurrence of configuration variation due to centrifugal force and wind pressure created by rotation. Further, the pattern formation is carried out by photolithography, thereby making it possible to form a resin film pattern required for CSP process with high accuracy.

Further, with the application of the photosensitive resin using inkjet, it becomes easy to form a thick resin film with a patterning, which is conventionally difficult with photolithography. Further, with the application of the photosensitive resin using inkjet, a resin film of regionally varing thickness can be formed.

With spin-coating, the film thickness complicatedly varies due to the influences of the centrifugal force by rotation, wind pressure, and the configuration of the surface, and therefore the thickness needs to be controlled in consideration of this variation. By contrast, with inkjet, the amount of application can be adjusted by changing the amount of discharge from the inkjet head, and therefore the thickness can be easily controlled and the degree of freedom is high as compared to spin-coating. Further, multi-layered coating can be easily done.

For the reasons above, the present invention is effective for forming a resin film in good quality on a wafer on which projections and recesses are formed due to wiring lines and the like. The advantageous effect of the invention is remarkable particularly in a large-diameter wafer of, for example, 300 mm, 450 mm or the like.

Further, in the formation of a resin film having a thickness of 1 μm or greater after curing (thick film), dripping and flowing easily occur due to its large amount of application, which makes it difficult to assure a predetermined shape. In order to avoid this, the multi-layered coating can be effectively employed to form a qualified resin film economically. The above-described effect is further prominent when the thickness of the resin film after curing is 10 μm or greater or even 20 μm or greater.

With the invention, inkjet can be effectively utilized while keeping the throughput of application, and thus the reduction of cost and the improvement of reliability in CSP process can be both realized.

What is claimed is:

1. A method of manufacturing a semiconductor device, comprising:
preparing a semiconductor substrate comprising a connection pad to electrically connect to a circuit element formed on a main surface, or a rewiring line connected to the connection pad,
forming an insulating photosensitive resin film on the substrate with an exclusion of at least an edge portion of the substrate by inkjet;
patterning the photosensitive resin film by photolithography; and
forming a rewiring line, UBM or an electrode for external connection on the substrate on which the patterned photosensitive resin film is formed.

2. The method of claim 1, wherein
the patterning comprises:
forming an opening to expose a dicing line of the substrate or forming an opening for a through-hole to connect to the connection pad or the rewiring line, and
thermally curing, after the forming the opening, the photosensitive resin film to remain as an insulating film.

3. The method of claim 2, wherein
the forming the photosensitive resin film comprises discharging a liquid photosensitive resin material from inkjet heads in uniform amount onto one entire surface of the substrate with the exclusion of the edge portion, and performing edge correction which corrects an amount of discharge in a vicinity of the edge portion of the substrate.

4. The method of claim 2, wherein
the forming the photosensitive resin film comprises performing edge correction which correct an amount of discharge in a vicinity of the edge portion of the substrate, and applying the photosensitive resin material more to a recess portion than to a projecting portion of the substrate to reduce or eliminate projections and recesses in the substrate after thermally curing the photosensitive resin film.

5. The method of claim 2, wherein
the forming the photosensitive resin film comprises discharging a liquid photosensitive resin material from inkjet heads selectively or non-uniformly onto an area of the substrate with the exclusion of the edge portion, thereby
(a) forming a resin film selectively on a partial region of the area, or
(b) forming a resin film comprising a surface with projections and recesses.

6. The method of claim 5, wherein
the forming the photosensitive resin film comprises halting the discharging of the liquid photosensitive resin material on at least a part of a region for a dicing line of the substrate to form a recess or an opening in the region for a dicing line.

7. The method of claim 2, wherein
the forming the photosensitive resin film comprises thinning the photosensitive resin film in a portion for the through-hole to be formed by the photolithography and a vicinity region thereof, as compared to other portions, and
the patterning comprises patterning a thinned region of the photosensitive resin film.

8. The method of claim 1, wherein
the forming the photosensitive resin film comprises: forming a first resin layer in a semi-cured state by applying a first photosensitive resin material to the substrate in an area excluding at least the edge portion, and thereafter drying, and subsequently, forming a second resin layer in a semi-cured state by applying a second photosensitive resin material to the substrate in the area excluding at least the edge portion, and thereafter drying, thereby forming an intermediate lamination film;
the patterning comprises patterning the intermediate lamination film and thermally curing the intermediate lamination film after the patterning to remain as an insulating film in which the first and second resin layers are integrated.

9. The method of claim 8, wherein
each of the first and second resin layers are formed by discharging a liquid photosensitive resin material from inkjet heads in uniform amount onto one entire surface of the substrate with the exclusion of the edge portion, and performing edge correction which correct an amount of discharge in a vicinity of the edge portion of the substrate.

10. The method of claim 8, wherein
at least one of the first and second resin layers are formed by discharging the liquid photosensitive resin material from inkjet heads selectively in a partial region of the substrate to reduce projections and recesses on the substrate after thermally curing the intermediate lamination film.

11. The method of claim 8, wherein
the forming the intermediate lamination film comprises forming at least one of the first and second resin layers by discharging the liquid photosensitive resin material from inkjet heads selectively in a partial region of the substrate to form an intermediate lamination film comprising regions of different thickness.

12. The method of claim 11, wherein
the forming the intermediate lamination film comprises:
forming a first resin layer in a semi-cured state by applying a first photosensitive resin material at uniform amount to the substrate, and thereafter drying; and
subsequently, forming a second resin layer in a semi-cured state by applying a second photosensitive resin material to the substrate in the area excluding a portion for a dicing line or a portion for an opening formed by patterning of the photolithography, and thereafter drying.

13. The method of claim 11, wherein
when discharging the photosensitive resin material selectively in the partial region, a nozzle diameter of the inkjet head is reduced, the amount of discharge of droplets is reduced, or a viscosity while discharging is raised as compared to the case of applying the photosensitive resin material in a uniform amount.

14. The method of claim 1, wherein
the forming the photosensitive resin film comprises: forming a first photosensitive resin film on the substrate with the exclusion of the at least the edge portion, and forming a second photosensitive resin film on the first photosensitive resin film such as to expand outward from the first photosensitive resin film; and
the patterning comprises patterning such that the second photosensitive resin film remains within an inner side of the first photosensitive resin film.

15. The method of claim 1, wherein
the forming the photosensitive resin film comprises:
forming an insulating first photosensitive resin film by inkjet such as to comprise a prominence in an outer peripheral portion of the substrate; and
forming an insulating second photosensitive resin film on the first photosensitive resin film by inkjet such as to be located on an inner side with respect to the prominence.

16. A method of manufacturing a semiconductor device, comprising: forming a first organic resin film, forming a second organic resin film, and forming at least one of a rewiring line, a UBM and a electrode for external connection, on a semiconductor substrate comprising a connection pad to electrically connect to a circuit element formed on a main surface thereof, or a rewiring line connected to the connection pad,
wherein
the forming the first organic resin film comprises applying an insulating organic resin material to the substrate with the exclusion of an edge portion thereof by inkjet, and thereafter forming a pattern by photolithography,
the forming the second organic resin film comprises applying an insulating organic resin material selectively or non-uniformly in at least a part of an area of the substrate excluding the edge portion by inkjet, thereby (a) forming a resin film selectively in a partial region within the area, (b) forming a resin film comprising a surface with projections and recesses, or (c) reducing or eliminating projections and recesses in the substrate after thermally curing the photosensitive resin film, and
the forming the pattern by the photolithography using the photosensitive material as the first organic resin film comprises exposing the first organic resin film selectively and thereafter developing the exposed film.

17. The method of claim 16, wherein
the first organic resin film is formed to have an opening in a portion above the connection pad or wiring line, on the substrate,
the rewiring line, the UBM or the electrode for external connection is formed on the first organic resin film such as to connect to the connection pad or rewiring line via the opening, and
the second organic resin film is formed on the first organic resin film and the rewiring line or an peripheral portion of the electrode for external connection, such as to have an opening above the rewiring line or a part of a portion where the electrode for external connection is formed.

18. The method of claim 16, wherein
the second organic resin film is formed in such a manner that a pattern requiring a predetermined processing accuracy is formed by photolithography, and a pattern only requiring a processing accuracy which is lower than the predetermined processing accuracy is formed by inkjet.

19. A method of manufacturing a semiconductor device, comprising:
preparing a semiconductor-chip buried substrate which includes a plurality of semiconductor chips each comprising a connection pad to electrically connect to a circuit element, or a rewiring line connected to the connection pad are disposed, and side portion of the plurality of semiconductor chips are buried with an insulating film;
forming an insulating photosensitive resin film on the semiconductor-chip buried substrate with the exclusion of at least an edge portion of the substrate by inkjet;
patterning the photosensitive resin film by photolithography; and
forming a rewiring line, UBM or an electrode for external connection on the semiconductor-chip buried substrate on which the patterned photosensitive resin film is formed.

20. The method of claim 19, wherein
the patterning comprises:
forming an opening to expose a dicing line of the semiconductor-chip buried substrate or forming an opening for a through-hole to connect to the connection pad or the rewiring line, and
thermally curing, after the forming the opening, the photosensitive resin film to remain as an insulating film.
